(19) United States
(12) Patent Application Publication
(10) Pub. No.: US 2024/0296268 A1
(43) Pub. Date: Sep. 5, 2024

(54) METHODS OF SELECTING DEVICES IN CIRCUIT DESIGN

(71) Applicant: TAIWAN SEMICONDUCTOR MANUFACTURING COMPANY, LTD., Hsinchu (TW)

(72) Inventors: Fong-Yuan CHANG, Hsinchu (TW); Hui Yu LEE, Hsinchu (TW); Yu-Hao CHEN, Hsinchu (TW); Tian-Jian WU, Hsinchu (TW); Tien-Chien HUANG, Hsinchu (TW); Manjo Kumar ENUGULA, Hsinchu (TW); Yu-Lin WEI, Hsinchu (TW); Jyun-Hao CHANG, Hsinchu (TW)

(21) Appl. No.: 18/337,262

(22) Filed: Jun. 19, 2023

Related U.S. Application Data
(60) Provisional application No. 63/488,004, filed on Mar. 2, 2023.

(51) Int. Cl. G06F 30/31; G06F 30/323; G06F 30/327

(52) U.S. Cl. CPC G06F 30/31; G06F 30/323; G06F 30/327

(57) ABSTRACT

A method includes tagging source PDK devices (SPDs) in a source-circuit design (SCD); generating a source design simulation database (SDSD) based on source design key performance indicator (KPI) simulation data of the SPDs in the SCD; generating a target process design kit (PDK) simulation database (TPSD) based on target design KPI simulation data of a plurality of target-PDK devices (TPDs); creating a matching table based on the SDSD and the TPSD; matching, based on the matching table, one or more TPDs from the TPSD with each SPD in the SDSD based on SPD KPIs; ranking the one or more TPDs matched from the TPSD with each SPD in the SDSD based on the SPD KPIs; and exchanging, based on a migration mapping table that includes a one-to-one relationship for TPDs to the SPDs in the SCD, one or more SPDs in the SCD with one-to-one relational TPDs.

### PRIORITY CLAIM AND CROSS-REFERENCE

The present application claims the benefit of Provisional Application No. 63/488,004, filed Mar. 2, 2023, which is incorporated in entirety herein by reference.

### BACKGROUND

The trend in miniaturizing integrated circuits (ICs) has resulted in smaller devices which consume less power yet provide more functionality at higher speeds. The miniaturization process has further resulted in stricter design and manufacturing specifications and reliability challenges. Various electronic design automation (EDA) tools generate, optimize, and verify standard cell layout designs for ICs while ensuring that the standard cell layout design and manufacturing specifications are met.

### BRIEF DESCRIPTION OF THE DRAWINGS

Aspects of the embodiments are best understood from the following detailed description when read with the accompanying figures. In accordance with the standard practice in the industry, various features are not drawn to scale. The dimensions of the various features are able to be arbitrarily increased or reduced for clarity of discussion.

FIG. 1 is a block diagram of an analog design migration, in accordance with some embodiments;

FIG. 2A is a flow diagram of a method for tagging electrical devices in source-circuit designs, in accordance with some embodiments;

FIG. 2B is a pictorial block diagram of a circuit extraction process, in accordance with some embodiments;

FIG. 3A is a table of hierarchies usable for tagging and categorizing devices, in accordance with some embodiments;

FIG. 3B is a tagging table of tagged and categorized devices, in accordance with some embodiments;

FIG. 4, is a block diagram of a process to determine functionality for source-circuit design instances, accordance with some embodiments;

FIG. 5 is a tagging table after a method for tagging electrical devices in source-circuit designs, in accordance with some embodiments;

FIG. 6 is a flowchart diagram of a method for generating a source design simulation key performance indicator (KPI) database, in accordance with some embodiments;

FIG. 7 is a tagging table after a netlist simulation based on a tagged source-circuit design, in accordance with some embodiments;

FIG. 8 is a flowchart diagram of a method for generating a target-PDK device simulation KPI database, in accordance with some embodiments;

FIG. 9 is a tagging table after a netlist simulation based on a tagged target-PDK devices, in accordance with some embodiments;

FIG. 10 is a flowchart diagram of a method for creating a matching table, in accordance with some embodiments;

FIG. 11 is a pre-created matching table, in accordance with some embodiments;

FIG. 12 is a process flow diagram for creating a screening/ranking condition table based upon a pre-created matching table and a netlist simulation based on a tagged source-circuit design, in accordance with some embodiments;

FIG. 13 is a flow diagram of a method for screening and ranking target-PDK devices, in accordance with some embodiments;

FIG. 14 is a 1-to-1 table of a 1-to-1 representation between source-PDK devices and target-PDK devices, in accordance with some embodiments;

FIG. 15 is a flow diagram of a method for generating a mapping table to migrate a source-PDK design to a target-PDK design, in accordance with some embodiments;

FIG. 16 is a mapping table, in accordance with some embodiments;

FIG. 17 is a flow chart diagram of a method for determining a best matched design composition in circuit design migration, in accordance with some embodiments;

FIG. 18 is a block diagram of an IC layout diagram generation system, in accordance with some embodiments; and

FIG. 19 is a block diagram of an IC manufacturing system and an IC manufacturing flow associated therewith, in accordance with some embodiments.

### DETAILED DESCRIPTION

The following provides many different embodiments, or examples, for implementing different features of the provided subject matter. Specific examples of components, values, operations, materials, arrangements, or the like, are described below to simplify the present disclosure. These are, of course, examples and are unintended to be limiting. Other components, values, operations, materials, arrangements, or the like, are contemplated. For example, the formation of a first feature over or on a second feature in the description that follows is able to include embodiments in which the first and second features are formed in direct contact and are further able to include embodiments in which additional features are formed between the first and second features, such that the first and second features are unable to be in direct contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below.” “lower,” “above.” “upper” and the like, are used herein for ease of description to describe one element or feature's relationship to another element(s) or feature(s) as illustrated in the figures. The spatially relative terms are intended to encompass different orientations of the embodiments in use or operation in addition to the orientation depicted in the figures. The embodiments are able to be otherwise oriented (e.g., rotated 90 degrees or at other orientations) and the spatially relative descriptors used herein are able to likewise be interpreted accordingly.

In some embodiments, a method includes tagging source process design kit (PDK) devices in a source-circuit design; generating a source design simulation database based on source design key performance indicator (KPI) simulation data of the source-PDK devices in the source-circuit design; generating a target-PDK simulation database based on target design KPI simulation data of a plurality of target-PDK devices; creating a matching table, based on the source design simulation database; matching, based on the matching table, one or more target-PDK devices from the target-PDK simulation database with each source-PDK device in the source design simulation database based on source- PDK device KPIs; ranking the one or more target-PDK devices matched from the target-PDK simulation database with each source-PDK device in the source design simulation database based on the source-PDK device KPIs; and exchanging, based on a migration mapping table that includes a one-to-one relationship for target-PDK devices to the source-PDK devices in the source-circuit design, one or more source-PDK devices in the source-circuit design with one-to-one relational target-PDK devices.

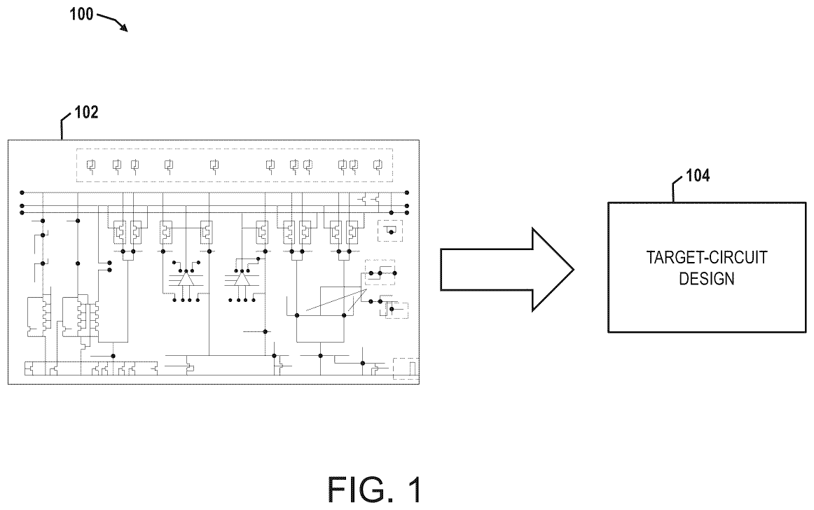

FIG. 1 is a block diagram of an analog design migration 100, in accordance with some embodiments.

In some embodiments, analog design migration 100 is a process where a source-circuit design 102 originally designed with a source technology is migrated to a target-circuit design 104. In some embodiments, source-circuit design 102 includes tens, hundreds, thousands, or even hundreds of thousands of devices, cells (in the context of EDA a cell is an abstract representation of a component within a schematic diagram or physical layout of an electronic circuit in software) or unit circuits (unit circuits are devices made up of more than one component) and are implemented with a source technology. In a non-limiting example, a unit circuit includes a complementary MOS (CMOS) inverter that includes a p-channel MOS (PMOS) and n-channel MOS (NMOS) with connected gates and connected drains, or a current mirror made up of two MOSFET transistors with connected gates. Therefore, a circuit is able to be broken down into the unit circuits which make up the larger circuit.

For purposes of discussion, a source technology is a technology which has been improved upon. In some embodiments, a source technology is technology that is considered outdated. In some embodiments, a target technology (e.g., the technology of the target-circuit design) includes smaller devices, devices which consume less power, or devices which provide more functionality at higher speeds.

In some embodiments, analog design migration 100 converts the devices, cells, or unit circuits in the source technology into devices, cells, or unit circuits in the target technology. In some embodiments, the source technology is an IC design originally designed with a transistor technology node, which has since been succeeded by a new technology node allowing for even smaller transistor technology.

In other approaches, analog design migration, which is the process of migrating an analog design from one process to another (e.g., an older process to a newer process such as when metal oxide semiconductor field-effect transistor (MOSFET) technology moves from a 20 nm technology to a 14 nm technology), is a labor (e.g., five or more engineers) and time intensive (e.g., one or more months) effort for circuit designers. A circuit design with multi-circuit functions complicates the migration even further. Additionally, a new PDK study according to another approach takes up to several weeks to perform due to millions of device combinations.

A PDK is a set of files used to model a fabrication process for the design tools used to design an IC. Designers use the PDK to design, simulate, draw, and verify the design before handing the design to a foundry to produce chips. In some embodiments, a PDK contains (1) a device library that includes symbols, device parameters, and PCells (parameterized cells that are pieces of programming code responsible for the process of creating the proper structure of PCell variants based on input parameters, such as length and width), (2) verification checks, (3) technology data, (4) rule files, (5) simulation models of primitive devices (SPICE or SPICE derivatives) that include transistors, capacitors, resistors, and inductors, and a (6) design rule manual.

In other approaches, a geometrical migration is based on a MOSFET equation where a width (W) length (L) ratio (W/L) remains the same. For example, a user is able to create a transistor PCell and then use different instances of the transistor PCell with different user-defined lengths and widths. In other approaches, each device is treated the same regardless of current flow. In other approaches there is no ability to differentiate functions in the source-circuit design (e.g., the original circuit to be migrated to a newer process).

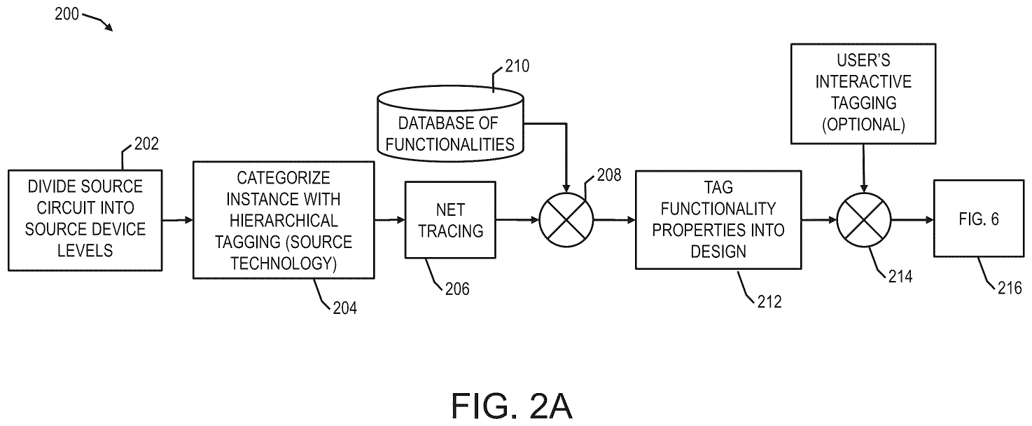

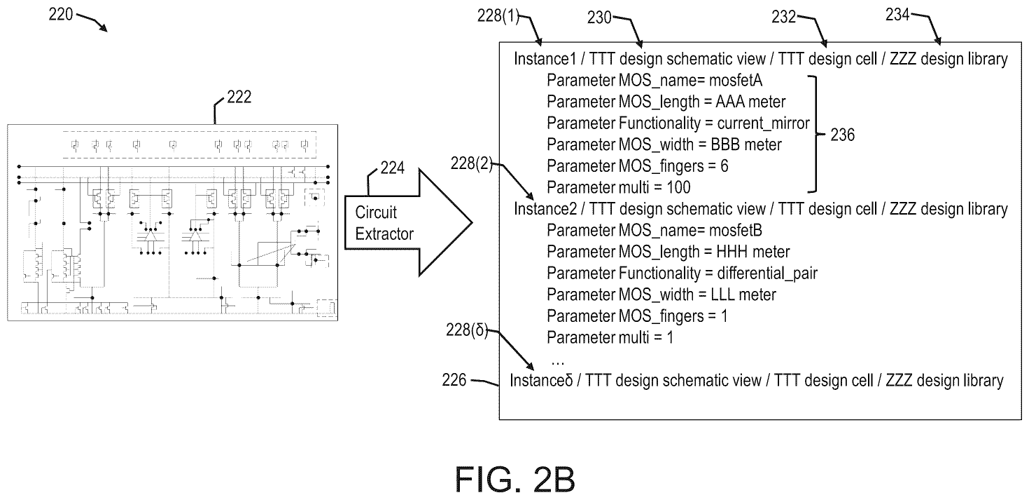

FIG. 2A is a flow diagram of a method for tagging electrical devices in source-circuit designs 200, in accordance with some embodiments.

In some embodiments, the method for tagging electrical devices in source-circuit designs 200 describes process tasks to apply physical tags and functionality tags with a circuit extractor to differentiate roles of source-PDK devices in a source-circuit design. While the processes of the method for tagging electrical devices in source-circuit designs 200 are discussed and shown as having a particular order, each process in the method for tagging electrical devices in source-circuit designs 200 is configured to be performed in any order unless specifically called out otherwise. The method for tagging electrical devices in source-circuit designs 200 is implemented as a set of processes, such as processes 202 through 216. The method for tagging electrical devices in source-circuit designs 200 is not limited to those processes but is applicable to other suitable processes.

At process 202 of the method for tagging electrical devices in source-circuit designs 200, a source-circuit design in electronic form (e.g., in SPICE form of a PDK), such as source-circuit design 102 or 222 (FIG. 2B) is broken down or divided into instances of source-PDK devices (e.g., devices, cells, unit circuits, or other suitable groupings). An IC (also referred to as a chip, a microchip, or monolithic IC) is a set of electronic circuits on one small flat piece (or “chip”) of semiconductor material, usually silicon. Large numbers of miniaturized transistors and other electronic components are integrated together on the chip. An electronic component is any basic discrete device or physical entity in an electronic system used to affect electrons or associated fields.

In some embodiments, a source-design circuit is a physical circuit. In some embodiments, a source-design circuit is an electronic circuit built or created with an electronic circuit simulator, such as simulation program with integrated circuit emphasis (SPICE). Electronic circuit simulators are used in ICs and board-level designs to check the integrity of circuit designs and to predict circuit behavior.

FIG. 2B is a block diagram of a circuit extraction process 220, in accordance with some embodiments.

In some embodiments, a circuit extractor (224 FIG. 2B) is usable to break down or divide source-circuit design 222 into source-PDK devices. The electric circuit extraction (further known as circuit extraction) is the translation of an IC layout back into an electrical circuit the IC is intended to represent. In some embodiments, topology recognition is applied to deconstruct source-circuit design 222 into source-PDK devices.

The output of circuit extractor 224 is a listing of instances 228(1), 228(2), through 228(δ) of source-PDK devices and parameter list 226 for each instance. In some embodiments, parameter list 226 is in the form of a text file, csv file, spreadsheet, table, or the like. Other suitable formats are within the contemplated scope of the embodiments.

In some embodiments, circuit extraction process 220 extracts instances 228(1), 228(2), through 228(δ) (e.g., source-PDK devices) from a source-circuit design 222 (e.g., in electronic form) and breaks source-circuit design 222 down into individual source-PDK device levels (e.g., instances) and several device level parameters in list of parameters 236. In the non-limiting example of FIG. 2B, source-circuit design 222 is an average sized reusable unit of logic or IC layout design with approximately 2,000 source-PDK devices to migrate.

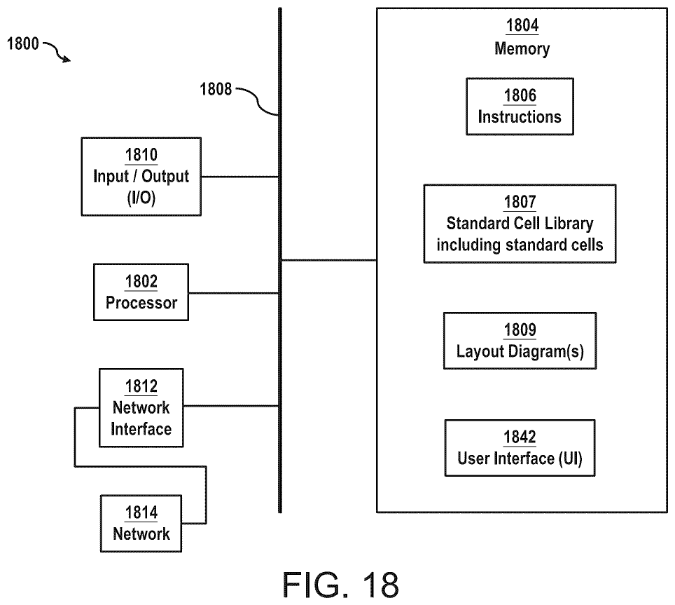

Circuit extractor 224 processes source-circuit design 222 and extracts the source-PDK devices of source-circuit design 222 and outputs parameter list 226. Parameter list 226 provides a listing of each source-PDK device (labeled as instances) in source-circuit design 222. Each instance provides reference to a design schematic view 230 (e.g., TTT design schematic view) of where the instance is found, a design cell 232 (e.g., TTT design cell) referencing a design cell type, and a design library 234 (e.g., ZZZ design library) from where the design cell derived from. In some embodiments, design library 234 is cell library 1807 of FIG. 18 discussed in more detail below.

Each instance of Instance1 228(1), Instance2 228(2) through Instanceδ 228(δ) (where δ represents the last of the total number of instances within source-circuit design 222; e.g., 8=2,000 in the non-limiting example of source-circuit design 222) includes a list of parameters 236 that describe various physical and functional aspects of the corresponding instance. In some embodiments, these aspects are parameters describing physical attributes, functional attributes, or both. Other suitable parameter attributes are within the contemplated scope of the embodiments. Continuing with the non-limiting example, list of parameters 236 include a name (e.g., MOS_name), a length (e.g., MOS_length), a functionality (e.g., current mirror, differential pair, inverter, or other suitable unit circuits), a width (e.g., MOS_width), a number of fingers (e.g., gates; MOS_fingers), and multi (indicating multi circuit functions).

Instances 228(1), 228(2) through 228(δ) are listed in parameter list 226. Parameter list 226 is the output of process 202 (FIG. 2A) and the process flows from process 202 to process 204. For purposes of the discussion, instance and source-PDK device are used interchangeably.

In FIG. 2A, at process 204 of the method for tagging electrical devices in source-circuit designs 200, each instance is categorized with one or more hierarchical tags based on the source technology of the source-circuit design, such as source-circuit designs 102 or 222. In some embodiments, each source-PDK device/instance is tagged with one or more grouping categories which allow for better searching in response to matching the source-PDK device with a targeted-PDK device in a migration evolution.

In some embodiments, the categorizing of source-PDK devices involves a hierarchical tagging methodology configured to categorize source-PDK devices in a source-circuit design. In some embodiments, a user is able to use an interactive interface, such as user interface (UI) 1842 (FIG. 18) to input hierarchical tagging to categorize devices in a source-circuit design. In some embodiments, a user is able to create user-defined hierarchy tags. In some embodiments, hierarchy tags are pre-determined.

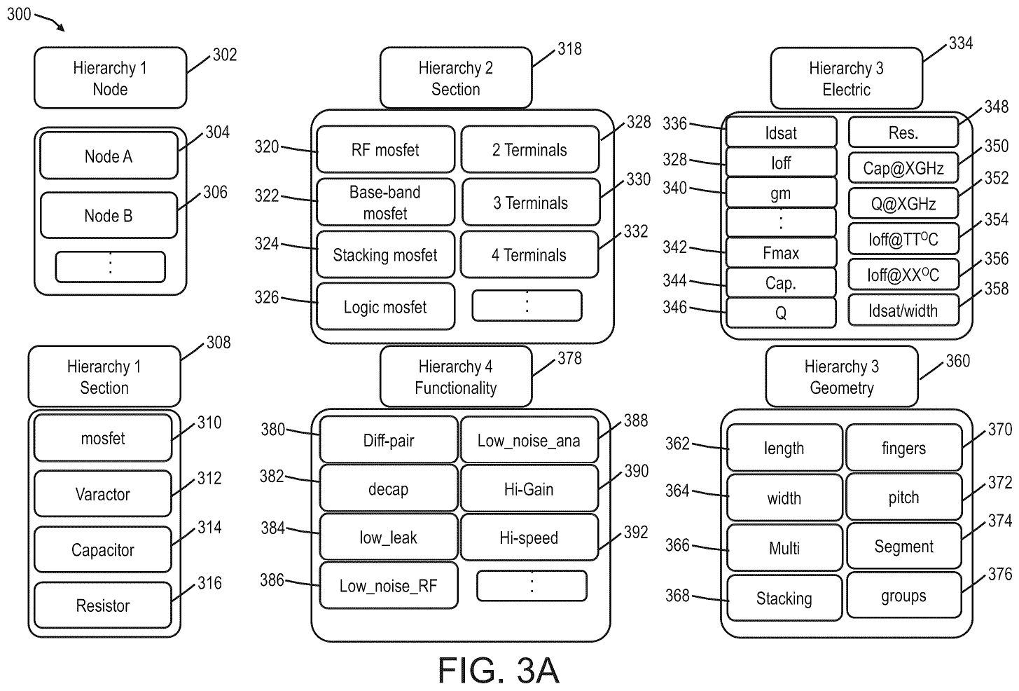

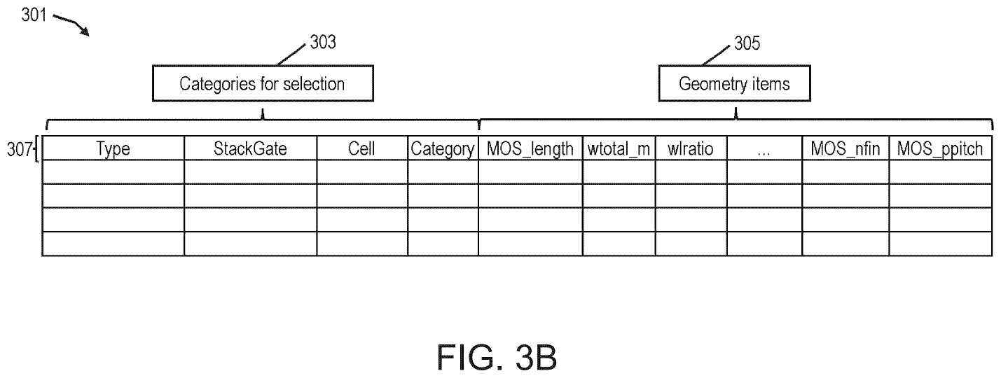

FIG. 3A is a table of hierarchies 300 usable for tagging and categorizing devices, in accordance with some embodiments.

A node hierarchy tag 302, identifies instances based upon a node or fabrication process used for the instance. In some embodiments, node A tag 304 represents instances created with a first fabrication process while node B tag 306 represents instances created with a second fabrication process.

A section hierarchy tag 308, identifies instances based on a device type. Device tags include MOSFET tag 310, varactor tag (or varicap diode, varactor diode, variable capacitance diode, variable reactance diode, or tuning diode) 312, and capacitor tag 314, resistor tag 316. Other suitable device tags are within the contemplated scope of the embodiments. Each of hierarchy tags 302 and 308 have the highest hierarchy (hierarchy 1).

Section hierarchy tag 318, identifies instances based on a device type subset. Device tags include RF MOSFET tag 320 (is a type of power transistor designed for radio-frequency applications), base-band MOSFET tag 322 (a transistor designed for a range of frequencies), stacking MOSFET 324 tag (a type of power MOSFET that uses P+ columns that penetrate the N-epitaxial layer), logic MOSFET tag 326 (designed to turn on fully from the logic level of a microprocessor), a two-terminal device tag 328, a three-terminal device tag 330, and a four-terminal device tag 332. Other suitable device tags are within the contemplated scope of the embodiments. Section hierarchy tag 318 has the second-highest hierarchy (hierarchy 2) after hierarchy 1.

An electric hierarchy tag 334, identifies instances based upon electrical parameters. Electrical tags include Idsat tag 336 (the drain current measured when the transistor is biased in the saturation region), Ioff tag 338 (the current into a circuit node when the device or a portion of the device affecting that circuit node is in the off state), gm tag 340 (trans conductance), Fmax tag 342 (the maximum clock rate at which a device is guaranteed to operate), Cap. tag 344 (capacitance), Q tag 346 (quality factor corresponds to the electric energy stored in the circuit divided by the energy dissipated in one period), Res. tag 348 (resistance), Cap@XGHz tag 350 (capacitance at XGHz), Q@XGHz tag 352 (quality factor at XGHz), Ioff@TT° C. tag 354, Ioff@XX° C. tag 356, and Idsat/width ratio tag 358. Other suitable electrical tags are within the contemplated scope of the embodiments.

A geometrical hierarchy tag 360, identifies instances based on geometrical parameters. Geometrical tags include length tag 362 (length of transistor), width tag 364 (width of transistor), multi tag 366 (circuit functions), stacking tag 368 (number of stacks), fingers tag 370 (number of gates), pitch tag 372 (the distance is measured from center-to-center of two adjacent gates), segment tag 374, and groups tag 376. Other suitable geometrical tags are within the contemplated scope of the embodiments. Each of hierarchy tags 334 and 360 have the third-highest hierarchy tagging (hierarchy 3), after hierarchy 2 and hierarchy 1.

A functional hierarchy 378, identifies instances based on functionality. Functional tags include diff-pair tag 380 (a two transistor differential amplifier), decap tag 382 (a charge storing device made of capacitors and used to support a current requirement in a power delivery network), low_leak tag 384 (low current leakage), low_noise_RF tag 386 (low RF noise), low_noise_ana tag 388 (low analog noise), hi-gain tag 390 (high gain), and hi-speed tag 392 (high speed). Other suitable functional tags are within the contemplated scope of the embodiments.

Functional hierarchy tag 378 has the fourth-highest hierarchy tagging (hierarchy 4), after hierarchy 3, hierarchy 2, and hierarchy 1.

FIG. 3B is a tagging table 301 of tagged and categorized devices, in accordance with some embodiments.

In FIG. 3B. output format of tagging table 301 is a table; however, the output format is able to be text, csv (comma-separated values), spreadsheet, or the like. Other suitable formats are within the contemplated scope of the embodiments. Categories for selection section 303 presents, in row 1 307, column headings based on type of device, number of stacked gates, a cell, and a category. Other suitable selections are within the contemplated scope of the embodiments. In some embodiments, a user is able to select hierarchy tags to be placed in categories for selection section 303. In some embodiments, a user is able to create a user-defined hierarchy tag to be placed in the categories for selection section 303. In some embodiments, each row, below row 1 307, of tagging table 301 represents a location for each instance (e.g., Instance1 228(1), Instance2 228(2), through Instanceδ 228(δ)) from parameter list 226).

In the example of FIG. 3B, geometry items section 305, from geometry hierarchy tag 360 are listed in tagging table 301. In some embodiments, each of hierarchy tags 302, 308, 318, 334, 360, or 378 are listed in row 1 307 of tagging table 301. In some embodiments, each of hierarchy tags 302, 308, 318, 334, and 378 have a separate section in tagging table 301 similar to geometry items section 305. Tagging table 301 is the output of process 204. Process flows from process 204 to process 206.

In FIG. 2A, at process 206 of method for tagging electrical devices in source-circuit designs 200, net tracing is performed to trace net connections between instances. In electronic design, net tracing outputs a netlist description of the connectivity of an electronic circuit, such as source-circuit design 102 or 222. In simplest form, a netlist consists of a list of the electronic components (source-PDK devices) in a circuit (e.g., source-circuit design) and a list of the connected nodes. A network (net) is a collection of two or more interconnected components. The structure, complexity and representation of netlists vary, but each netlist conveys connectivity information. Netlists provide instances, nodes, and attributes of the components. Process flows from process 206 to process 208.

At process 208 of method for tagging electrical devices in source-circuit designs 200. the net connections between instances are compared with database of functionalities 210 and a functionality tag is input for each instance of Instance1 228(1), Instance2 228(2), through Instanceδ 228(δ). A determination is made as to the functionality of each instance (source-PDK device) based on a comparison of known devices having known functionality.

Process flows from process 208 to process 212.

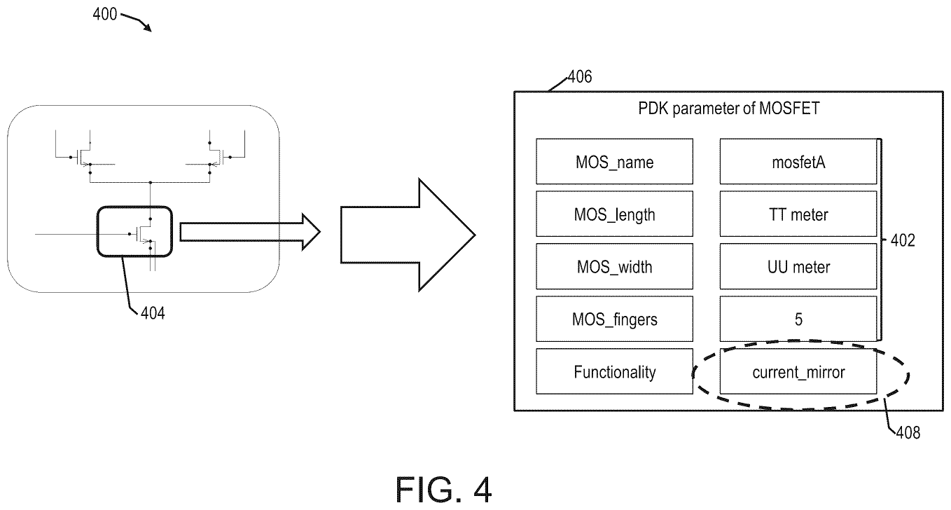

At process 212 of method for tagging electrical devices in source-circuit designs 200, the functionality tag for each instance is input into parameter list 406 (FIG. 4).

FIG. 4 is a block diagram of a process to determine functionality for source-circuit design instances, accordance with some embodiments.

In the process to determine functionality for source-circuit design instances 400, through net connections of a terminal of each source-PDK device, such as source-PDK device 404, the functionality of source-PDK device 404 in the source-design circuit is recognized and a PDK functionality parameter for source-PDK device 404 is filled in parameter list 406 (FIG. 4) at functionality block 408. The topology of the net tracing is pre-determined in database of functionalities 210. In a non-limiting example, in response to two MOSFETs having connected gate terminals while the drain terminals are separated, then these two MOSFETs are described as a current mirror.

At process 212 of the method for tagging electrical devices in source-circuit designs 200, one or more functionality tags for each instance are inputted into parameter list 406 (FIG. 4). A functionality identified in process 208 for each instance is inputted into a functionality block, such as functionality block 408 of a parameter list, such as parameter list 406. In the non-limiting example of FIG. 4, source-PDK device 404 is compared with database of functionalities 210 and identified as a current mirror 410. Continuing with the non-limiting example the functionality is inserted into functionality block 408 of parameter list 406. In some embodiments, parameter list 406 is used for case of description. In some embodiments, each of parameters 402 and the functionality in functionality block 408 are directly inputted into tagging table 301, in corresponding columns within geometry items section 305 (FIG. 3B) and functionality from functionality block 408 in type column of categories for selection section 303 in a corresponding row identifying source-PDK device 404.

In FIG. 2A, process flows from process 212 to process 214 of the method for tagging electrical devices in source-circuit designs 200, where a user is able to input additional tags into tagging table 301. In some embodiments, tagging table 301 is an interactive table and the user is able to input additional tags directly into tagging table 301.

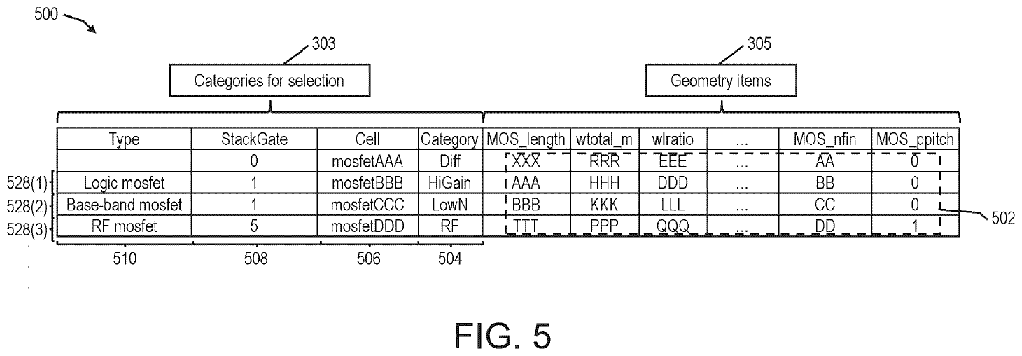

In FIG. 2A, process flows from process 214 to process 216, where tagging table 500 (FIG. 5) is output to process 602 of the method for generating source design simulation KPI database 600 a process for generating a source design simulation KPI database.

FIG. 5 is a tagging table 500 after a method for tagging electrical devices in source-circuit designs 200, in accordance with some embodiments.

In FIG. 5, tagging table 500 is similar to tagging table 301, with the exception that each instance, 528(1), 528(2), 528(3) . . . , includes geometry parameters 502 from parameter list 226 determined in process 202 of the method for tagging electrical devices in source-circuit designs 200, located under geometry items section 305 in tagging table 500. Under categories for selection section 303 of tagging table 500, category column 510 includes functionalities determined in process 208 of the method for tagging electrical devices in source-circuit designs 200. Cell column 506 includes a design cell from parameter list 226, such as design cell 232, for each instance, 528(1), 528(2), 528(3) . . . , determined in process 202 of the method for tagging electrical devices in source-circuit designs 200. Stackgate column 508 includes a stacked gate number for each instance, 528(1), 528(2), 528(3) . . . determined in process 202 of the method for tagging electrical devices in source-circuit designs 200. And, in column 504 a hierarchy tag for each instance, 528(1), 528(2), 528(3) . . . , from functionality hierarchy tag 378, determined in process 208 is included.

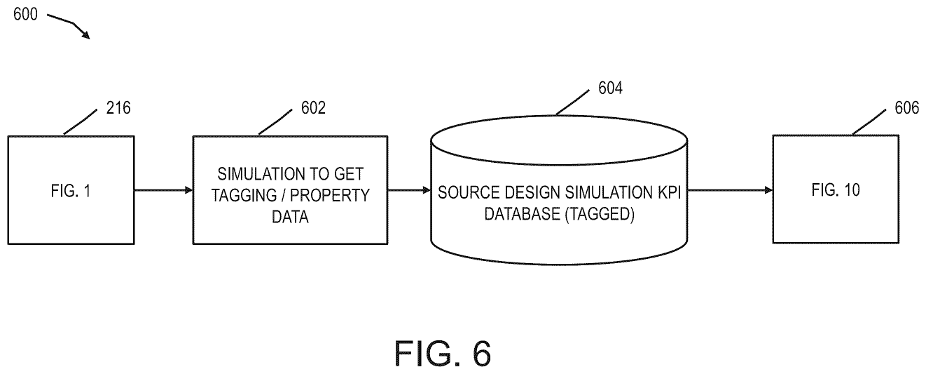

FIG. 6 is a flowchart diagram of a method for generating source design simulation KPI database 600, in accordance with some embodiments.

In some embodiments, the method for generating source design simulation KPI database 600 describes process tasks to store in a source design simulation KPI database the simulation results of a netlist simulation of tagged instances from the source-circuit design, such as source-circuit design 102 or 222. While the processes of the method for generating source design simulation KPI database 600 are discussed and shown as having a particular order, each process in the method for generating source design simulation KPI database 600 is configured to be performed in any order unless specifically called out otherwise. The method for generating source design simulation KPI database 600 is implemented as a set of processes, such as processes 602 through 606. The method for generating source design simulation KPI database 600 is not limited to those processes but is applicable to other suitable processes.

At process 602 of the method for generating source design simulation KPI database 600, tagging table 500 is translated into a simulation netlist format and a netlist simulation is performed. In some embodiments, a pre-created simulation netlist includes variable device parameters with symbols identifying the variables. In a non-limiting example, the symbols (e.g., %_% or $_$) identifying the variables include the form % width % or $length$. The symbols and variable device parameters are later replaced with source-circuit design device parameters from tagging table 500.

In another non limiting example, a pre-created netlist instance is presented as: XDUT ND NG NS NB % Instance % L=% MOS_length % W=% MOS_width % finger=% MOS_fingers % multi=% MOS_multi %. Continuing with the non-limiting example, the source-circuit design's device parameters for an instance are inputted into the variables to produce: XDUT ND NG NS NB mosfet L=XX W=YY finger=ZZ multi=KK, where XX, YY, ZZ, and KK are positive integers.

In response to source-circuit design device parameters being inserted into the pre-created netlist and replacing the variable device parameters, a netlist simulation is performed. The output of the tagged netlist simulation is KPI data for each instance. In a non-limiting example, the KPI data includes electrical measurement data, such as Idsat, ioff, and Cgg. Other suitable electrical measurements are within the contemplated scope of the embodiments. Thus, through the tagged netlist simulation, each instance (source-PDK device) includes electrical KPI measurement data. This electrical KPI measurement data is useful in matching source-PDK devices with target-PDK devices through matching similar electrical performances. Process flows from process 602 to process 604.

At process 604 of the method for generating source design simulation KPI database 600, the output of the simulation is stored into a source design simulation KPI database. In some embodiments, the simulation is stored in text, csv, spreadsheet, or the like. Other suitable formats are within the contemplated scope of the embodiments.

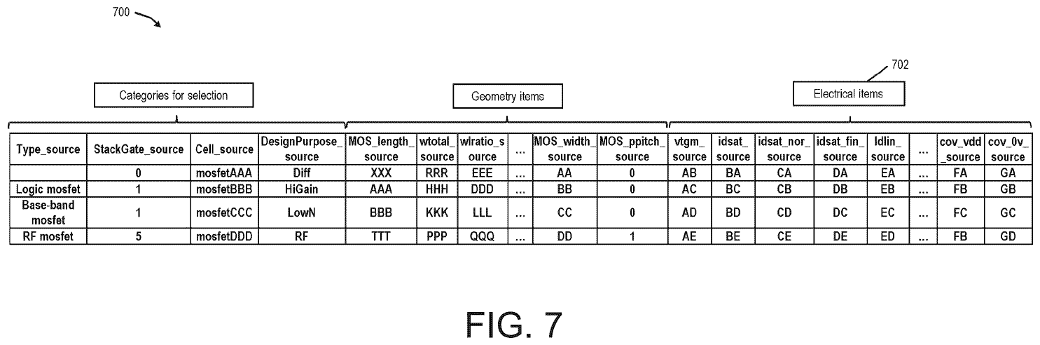

FIG. 7 is a tagging table 700 after a netlist simulation based on a tagged source-circuit design, in accordance with some embodiments. Tagging table 700 is similar to tagging table 500 with the exception of electrical items section 702 is added to capture the electrical KPI data of the netlist simulation. In some embodiments, one or more columns in electrical items section 702 include numerical values of a respective electrical value identifier, where the numerical value is determined in the netlist simulation of process 602. Tagging table 700 is stored in the source design simulation KPI database at process 604. In some embodiments, each column heading in electrical items section 702 is a hierarchy tag from electric hierarchy tag 334 (e.g., tags 336-358).

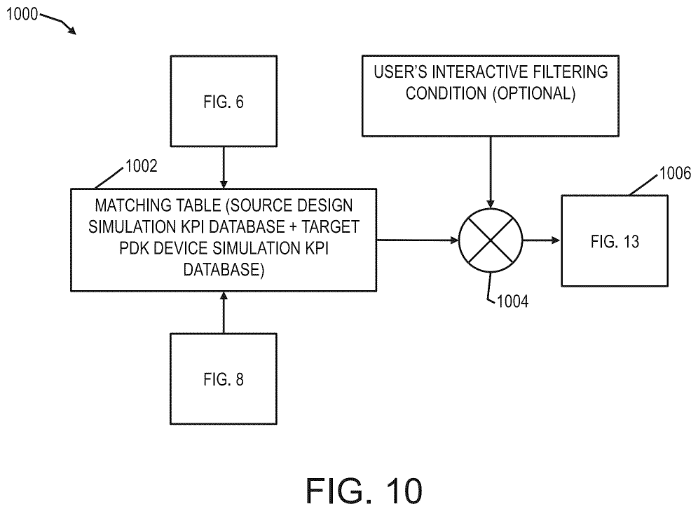

At process 606 of method for generating source design simulation KPI database 600, process flows from process 606 to process 1002 where tagging table 700 is used in a method to create a matching table 1000 (FIG. 10).

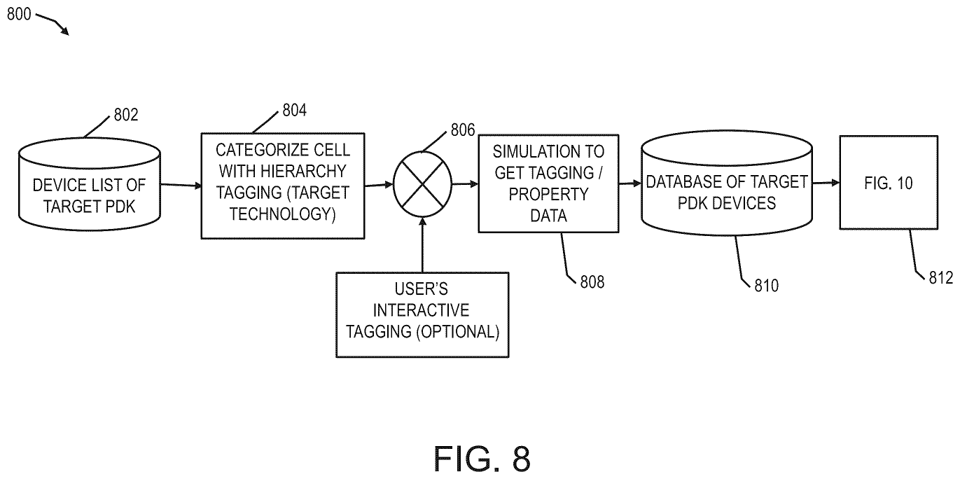

FIG. 8 is a flowchart diagram of a method for generating target-PDK device simulation KPI database 800, in accordance with some embodiments.

In some embodiments, the method for generating target-PDK device simulation KPI database 800 describes process tasks to store in a target-PDK device simulation KPI database the simulation results of a netlist simulation of tagged instances from target-PDK devices. While the processes of the method for generating target-PDK device simulation KPI database 800 are discussed and shown as having a particular order, each process in method for generating target-PDK device simulation KPI database 800 is configured to be performed in any order unless specifically called out otherwise. The method for generating target-PDK device simulation KPI database 800 is implemented as a set of processes, such as processes 802 through 812. The method for generating target-PDK device simulation KPI database 800 is not limited to those processes but is applicable to other suitable processes.

At process 802 of the method for generating target-PDK device simulation KPI database 800, target-PDK devices are parsed, and a device list is created in text, csv, spreadsheet, or the like. Other suitable formats are within the contemplated scope of the embodiments. In some embodiments, target-PDK devices are devices already developed in the target technology in which the source-circuit design, such as source-circuit design 102 or 222, is being migrated. In some embodiments, target-PDK devices are devices developed in technologies developed after the source-circuit design, such as source-circuit design 102 or 222. In some embodiments, target-PDK devices are devices implemented with a technology considered advanced over the source-circuit design technology. Process flows from process 802 to process 804.

At process 804 of the method for generating target-PDK device simulation KPI database 800, target-PDK devices (or target cells or target unit circuits) are categorized with hierarchy tagging and a tagging table is created. Process 804 is similar to process 204. Therefore, for purposes of brevity and repetition of already discussed material, process 804 is not discussed further. Process flows from process 804 to process 806.

At process 806 of the method for generating target-PDK device simulation KPI database 800, a tagging table, created in process 804, is translated into a simulation netlist format. Process 806 is similar to process 208. Therefore, for purposes of brevity and repetition of already discussed material, process 806 is not discussed further. Process flows from process 806 to process 808.

At process 808 of the method for generating target-PDK device simulation KPI database 800, a netlist simulation is executed with a pre-created netlist which has the variables substituted with target-PDK device parameters. Process 808 is similar to process 602. Therefore, for purposes of brevity and repetition of already discussed material, process 808 is not discussed further. Process flows from process 808 to process 810.

At process 810 of the method for generating target-PDK device simulation KPI database 800, the netlist simulation of process 808, is output to a target-PDK device simulation KPI database. Process 810 is similar to process 604. Therefore, for purposes of brevity and repetition of already discussed material, process 810 is not discussed further. Process flows from process 810 to process 812.

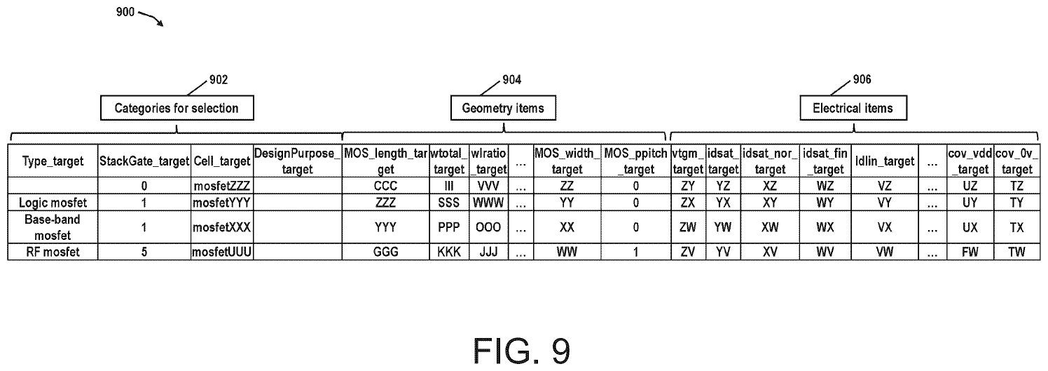

FIG. 9 is a tagging table 900 after a netlist simulation based on a tagged target-PDK devices, in accordance with some embodiments. Tagging table 900 is similar to tagging table 700 in structure, but the values in categories for selection 902, geometry items 904, and electrical items 906 are different from tagging table 700 as the values of tagging table 900 are representative of target-PDK devices and not the source-PDK devices of tagging table 700. Tagging table 900 is stored in the target-PDK device simulation KPI database at process 810.

At process 812 of method for generating target-PDK device simulation KPI database 800, process flows from process 812 to process 1002 and tagging table 900 is used by a method to create a matching table 1000 (FIG. 10).

FIG. 10 is a flowchart diagram of a method for creating a matching table 1000, in accordance with some embodiments.

In some embodiments, the method for creating a matching table 1000 describes process tasks to create a matching table from a pre-created screening/ranking condition table. While the processes of the method to create a matching table 1000 are discussed and shown as having a particular order, each process in the method to create a matching table 1000 is configured to be performed in any order unless specifically called out otherwise. The method to create a matching table 1000 is implemented as a set of processes, such as processes 1002 through 1006. The method to create a matching table 1000 is not limited to those processes but is applicable to other suitable processes.

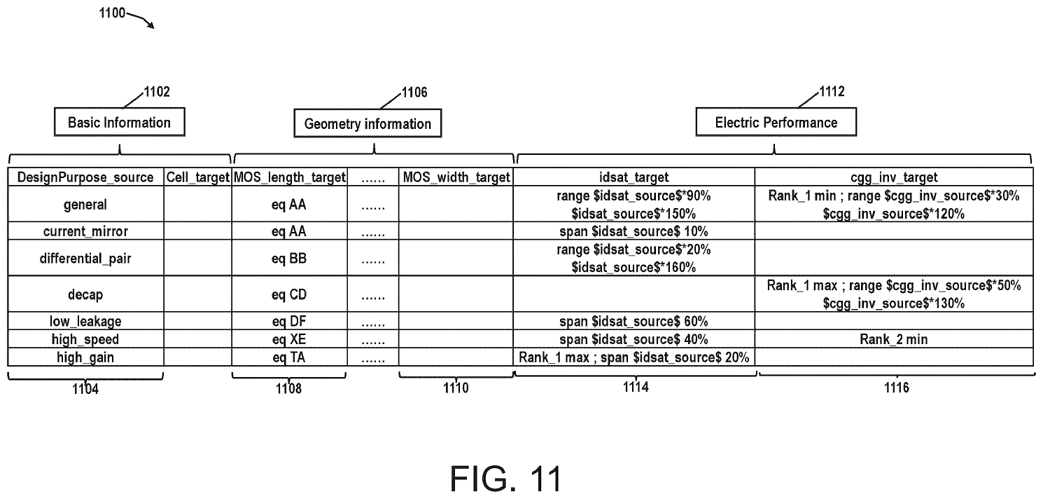

FIG. 11 is a pre-created matching table 1100, in accordance with some embodiments.

In FIG. 11, pre-created matching table 1100 includes a basic information section 1102 with a design purpose column 1104. In some embodiments, each design (general, current mirror, differential pair, decap, low leakage, high speed, or high gain. Other suitable designs are within the contemplated scope of the embodiments) within design purpose column 1104 includes tag identifiers from functional hierarchy tag 378 (e.g., functionality tag).

Pre-created matching table 1100 includes geometrical information section 1106 with a MOS length target column 1108 and a MOS width target column 1110. In some embodiments, equations, such as equations AA, BB, CD, EF, XE, and TA, are used for a desired geometry. In the non-limiting example of FIG. 11, the MOS length is targeted for a desired geometry. In some embodiments, one or more columns, such as MOS length target column 1108 and MOS width target column 1110, within geometrical information section 1106 is relatable to geometry hierarchy tag 360 (e.g., geometry).

Pre-created matching table 1100 includes electric performance section 1112 that includes one or more columns containing headings (e.g., idsat_target, cgg_inv_target, and other suitable electric performance parameters) relating to hierarchy tags from electric hierarchy tag 334.

In FIG. 10, at process 1002 of the method to create a matching table 1000, pre-created matching table 1100 is used to create a screening/ranking condition table 1200 (FIG. 2).

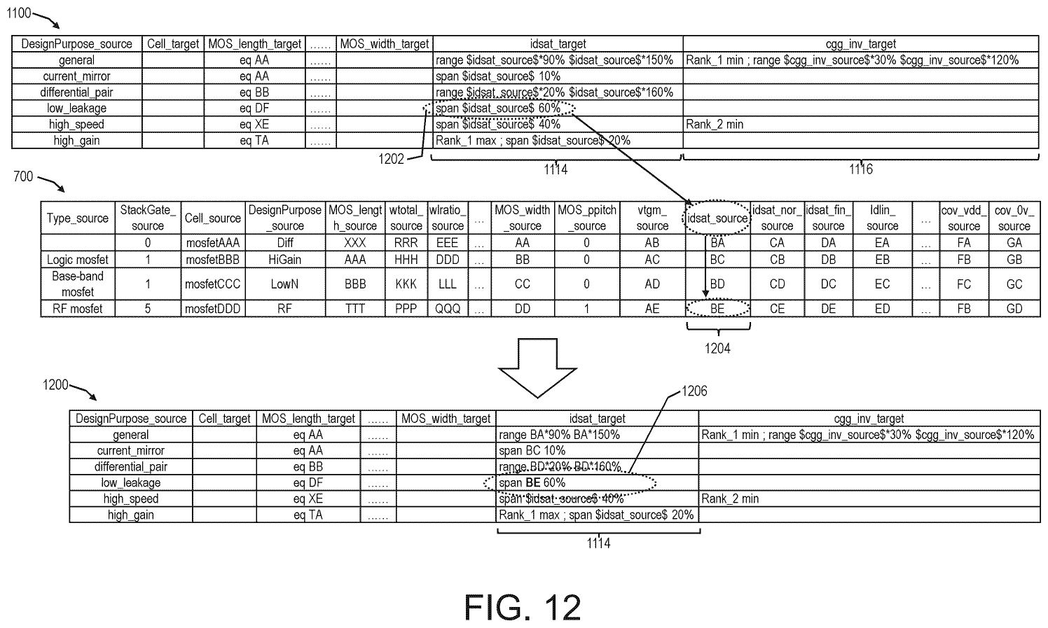

In FIG. 11, one or more equations are included in columns 1114 and 1116 of electric performance section 1112 in variable format with variable symbols. In a non-limiting example, equations, such as $idsat_source$ or % MOS_length %, where $_$ or %_% are beginning and ending symbols for a variable within the symbols to be searched. Continuing with the non-limiting example, in response to the variable $idsat_source$ being in row 4 within pre-created matching table 1100, then row four of idsat_source column of tagging table 700 (the netlist simulation based on a tagged source-circuit design) is matched and the value within row four of idsat_source column of tagging table 700 is inserted into pre-created matching table 1100 to create screening/ranking condition table 1200 (FIG. 12).

FIG. 12 is a process flow diagram for creating a screening/ranking condition table 1200 based upon a pre-created matching table and a netlist simulation based on a tagged source-circuit design, in accordance with some embodiments.

In a non-limiting example, a corresponding numerical value for a variable, such as variable equation 1202 (e.g., span $idsat_source$ 60%) from pre-created matching table 1100, is located within tagging table 700. As variable equation 1202 is in the fourth row of column 1114, reference is made to the fourth row of tagging table 700 and idsat_source column 1204. Continuing with the non-limiting example, the value within the fourth row of column 1204 replaces the $idsat_source$ variable in screening/ranking condition table 1200 as shown in variable equation 1206.

Variable equation 1202, $idsat_source$ identifies column 1204 to search for within tagging table 700 with the variable identifiers $$. In response to the variable name being identified (e.g., idsat_source), then according to a row number position of the variable (e.g., fourth row of pre-created matching table 1100), a numerical representation of the idsat_source from tagging table 700 within the source design simulation KPI database is located.

Continuing with the non-limiting example, variable equation 1202 is modified to variable equation 1206 (e.g., idsat_target=span BE 60%, where BE is a numerical value) to represent a condition in which to find one or more target-PDK devices in tagging table 900 of the target-PDK device KPI database, which match variable equation 1206. This process is continued until each variable from pre-created matching table 1100 is replaced by a numerical value.

Process flows from process 1002 to process 1004.

At process 1004 of method to create a matching table 1000, the user is able to modify screening/ranking condition table 1200 through an interactive interface, such as UI 1842 (FIG. 18). Process flows from process 1004 to process 1006.

At process 1006 of method to create a matching table 1000, process flows from process 1006 to process 1302 and screening/ranking condition table 1200 is used in a method for screening and ranking target-PDK devices 1300.

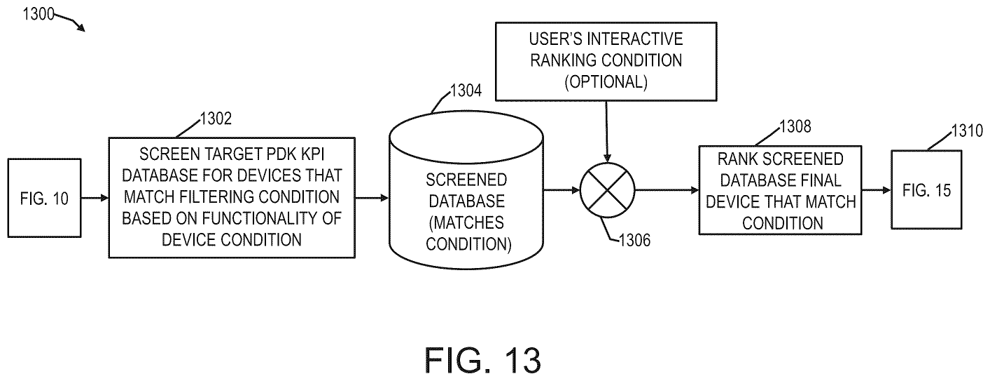

FIG. 13 is a flow diagram of a method for screening and ranking target-PDK devices 1300, in accordance with some embodiments.

In some embodiments, the method for screening and ranking target-PDK devices 1300 describes process tasks to screen and rank target-PDK devices. While the processes of the method for screening and ranking target-PDK devices 1300 are discussed and shown as having a particular order, each process in method for screening and ranking target-PDK devices 1300 is configured to be performed in any order unless specifically called out otherwise. The method for screening and ranking target-PDK devices 1300 is implemented as a set of processes, such as processes 1302 through 1310. The method for screening and ranking target-PDK devices 1300 is not limited to those processes but is applicable to other suitable processes.

In FIG. 13, at process 1302 of method for screening and ranking target-PDK devices 1300, matching target-PDK devices in the target PDK KPI database are identified based on screening/ranking condition table 1200.

In FIG. 12, operators, such as “span” within variable equation 1206 in screening/ranking condition table 1200 provide for an equation operation where span BE 60% means to select target-PDK devices where the idsat is:

Target-PDK device idsat=range between BE(1−0.7) to BE(1+0.7).

Each target-PDK device with an idsat within the range in the equation above is considered an eligible device for the screening process of process 1302.

Further, an equation having an “SS” operator indicates that the target-PDK data is equal to the numerical value directly after the SS operator (e.g., SS70 operator selects target-PDK device with a numerical value of 70 at the variable of interest, such as idsat).

Further, a range operator, such as “range” indicates each target PDK device in the range. In a non-limiting example, range BA*90% BA*150%indicates each target PDK device with values at this variable between 0.9BA and 1.5BA is selected as a potential target PDK device to be screened.

Process 1302 is performed for each row of screening/ranking condition table 1200 until one or more target-PDK devices are selected for each source-PDK device. Process flows from process 1302 to process 1304.

At process 1304 of the method for screening and ranking target-PDK devices 1300, screening/ranking condition table 1200 along with each of the screened target-PDK devices is stored in a screened database. Process flows from process 1304 to process 1306.

At process 1306 of the method for screening and ranking target-PDK devices 1300, a user is able, interactively, to input a ranking condition prior for the screened target-PDK devices being ranked at process 1308.

At process 1308 of the method for screening and ranking target-PDK devices 1300, a match target-PDK device within the screened database is determined based on ranking information of screening/ranking condition table 1200.

In FIG. 12, screening/ranking condition table 1200 includes ranking operators, within electric performance section 1112, such as column 1114, that are used to provide a ranking system for the selection of a screened target-PDK devices.

In a non-limiting example, a ranking operator includes “Rank_X”, where priority is determined such as Rank_1 is a priority 1, Rank_2 a priority 2, and the like. Another ranking operator includes a “max” operator where the target-PDK device with the largest KPI of that column heading (e.g., isat) is the matched target-PDK device. Another ranking operator includes a “min” operator where the target-PDK device with the smallest KPI of that column heading (e.g., isat) is the matched target-PDK device. Other suitable ranking operators are within the contemplated scope of the disclosure. Process flows from process 1308 to process 1310.

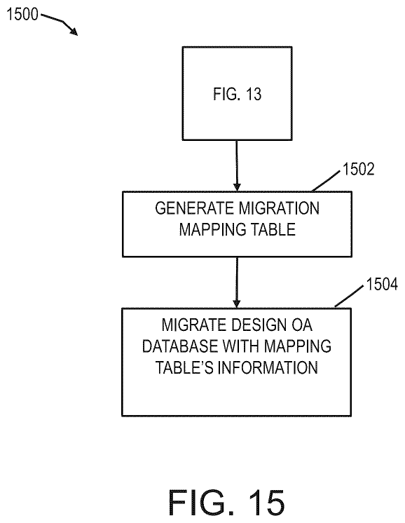

At process 1310 or method for screening and ranking target-PDK devices 1300, process flows from process 1310 to process 1502 where a 1-to-1 table 1400 is used in a method for generating a mapping table 1500 (FIG. 15) to migrate a source-design to the target-design.

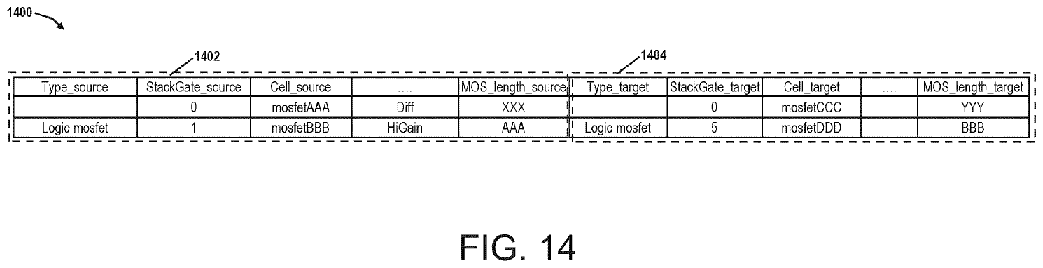

FIG. 14 is 1-to-1 table 1400 of a 1-to-1 representation between source-PDK devices and target-PDK devices, in accordance with some embodiments.

In FIG. 14, 1-to-1 table 1400 includes information regarding source-PDK devices in block 1402 and information regarding a target-PDK device in block 1404.

FIG. 15 is a flow diagram of a method for generating a mapping table 1500 to migrate a source-PDK design to a target-PDK design, in accordance with some embodiments.

In some embodiments, the method for generating a mapping table 1500 describes process tasks to migrate a source-PDK design to a target-PDK design. While the processes of the method for generating a mapping table 1500 are discussed and shown as having a particular order, each process in method for generating a mapping table 1500 is configured to be performed in any order unless specifically called out otherwise. The method for generating a mapping table 1500 is implemented as a set of processes, such as processes 1502 through 1504. The method for generating a mapping table 1500 is not limited to those processes but is applicable to other suitable processes.

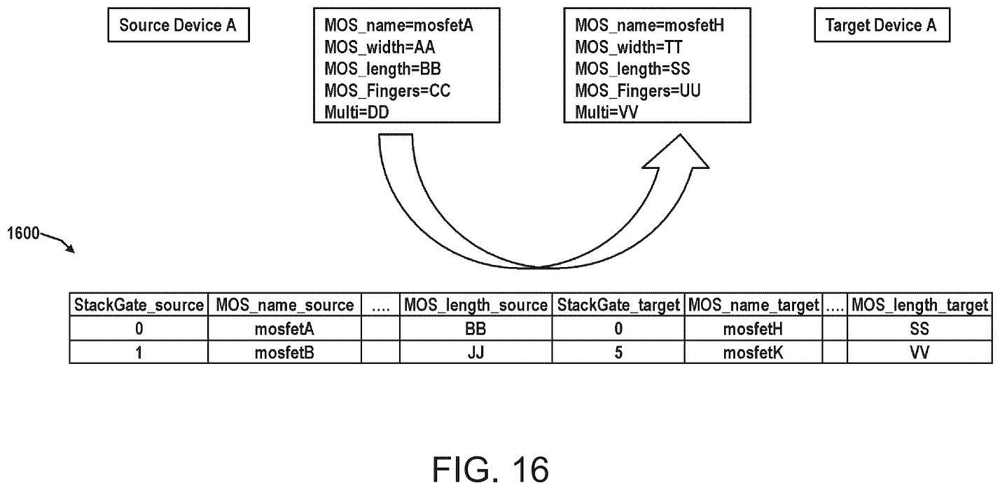

At process 1502 of the method for generating a mapping table 1500, a mapping table is generated based on 1-to-1 table 1400 information. 1-to-1 table 1400 is stripped of information not related to PDK related information in 1-to-1 table 1400. For example, for a mosfet, the PDK related parameters are MOS_length, MOS_width, MOS_pitch, MOS_name, multi, MOS_fingers, and “Functionality”. Other suitable PDK related parameters are within the contemplated scope of the disclosure. The output is a mapping table 1600 (FIG. 16).

FIG. 16 is a mapping table 1600, in accordance with some embodiments. While mapping table 1600 is shown as a table, a mapping table format is available in text, csv, or Excel. Other suitable formats within the contemplated scope of the disclosure. Process flows from process 1502 to process 1504.

At process 1504 of method for generating a mapping table 1500, instances in a source design schematic openAccess (OA) database are located according to mapping table 1600, and the source-PDK parameter is replaced with the matched target device's PDK parameter.

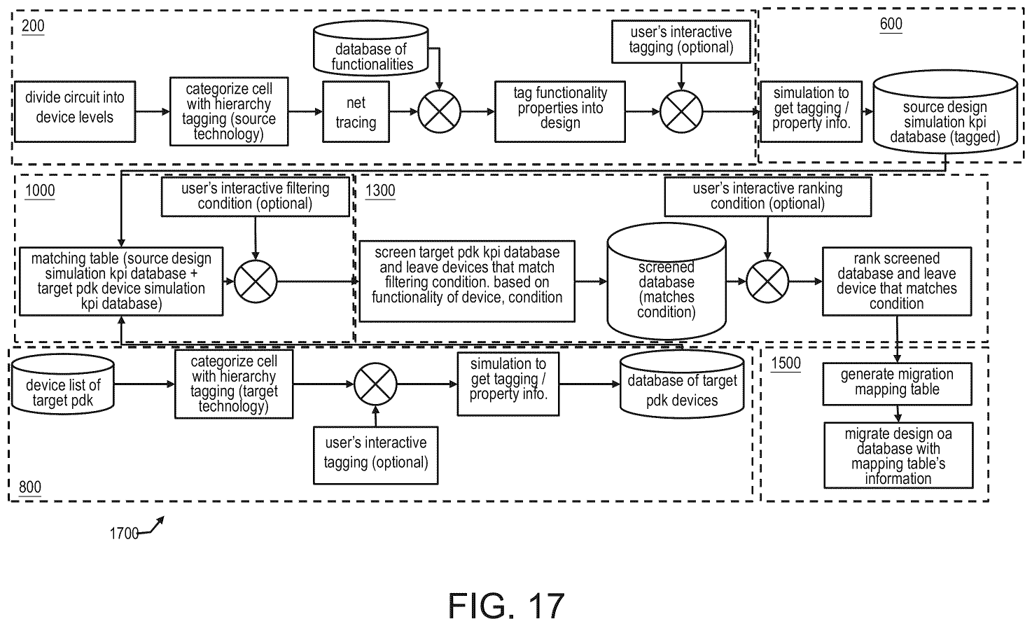

FIG. 17 is a flow chart diagram of a method for determining a best matched design composition 1700 in circuit design migration, in accordance with some embodiments.

In FIG. 17, the method for determining a best matched design composition 1700 in circuit design migration is a combination of the method for tagging electrical devices in source-circuit designs 200, the method for generating source design simulation KPI database 600, the method for generating target-PDK device simulation KPI database 800, the method for creating a matching table 1000, method for screening and ranking target-PDK devices 1300, and the method for generating a mapping table 1500 to migrate a source-design to the target-design.

In some embodiments, a tagging table, similar to tagging table 500, is output by method for tagging electrical devices in source-circuit designs 200 to a netlist simulator in a method for generating source design simulation KPI database 600. In some embodiments, a tagging table, similar to tagging table 900, is used to perform a netlist simulation and is output to a target-PDK device simulation KPI database in method for generating target-PDK device simulation KPI database 800. In some embodiments, a netlist simulation of a tagging table, similar to tagging table 500, is output to a source design simulation KPI database in method for generating source design simulation KPI database 600. In some embodiments, a matching table, similar to pre-created matching table 1100, accesses source design simulation KPI database to generate a screening/ranking condition table, similar to screening/ranking condition table 1200 in the method for creating a matching table 1000. In some embodiments, a screening/ranking condition table, similar to screening/ranking condition table 1200, in a method for creating a matching table 1000 is used to create a 1-to-1 table of source-PDK devices to target-PDK devices, similar to 1-to-1 table 1400, in a method for screening and ranking target-PDK devices 1300. In some embodiments, a 1-to-1 table of source-PDK devices to target-PDK devices, similar to 1-to-1 table 1400, is used to create a mapping table, similar to mapping table 1600, to directly map a source-circuit design to a target-source design in a method for generating a mapping table 1500 to migrate a source-design to the target-design.

FIG. 18 is a block diagram of IC layout diagram generation system 1800, in accordance with some embodiments.

Methods described herein of designing IC layout diagrams in accordance with one or more embodiments are implementable, for example, using IC layout diagram generation system 1800, in accordance with some embodiments.

In some embodiments, IC layout diagram generation system 1800 is a general-purpose computing device including a processor 1802 and a non-transitory, computer-readable storage medium 1804. Computer-readable storage medium 1804, amongst other things, is encoded with, i.e., stores, computer program code, i.e., a set of executable instructions 1806. Execution of instructions 1806 by processor 1802 represents (at least in part) an EDA tool which implements a portion or all a method, e.g., a method of generating an IC layout diagram described herein with respect to the drawings (hereinafter, the noted processes and/or methods).

Processor 1802 is electrically coupled to computer-readable storage medium 1804 via a bus 1808. Processor 1802 is further electrically coupled to an I/O interface 1810 by bus 1808. A network interface 1812 is further electrically connected to processor 1802 via bus 1808. Network interface 1812 is connected to a network 1814, so that processor 1802 and computer-readable storage medium 1804 connectable to external elements via network 1814. Processor 1802 is configured to execute instructions 1806 encoded in computer-readable storage medium 1804 to cause IC layout diagram generation system 1800 to be usable for performing a portion or all the noted processes and/or methods. In one or more embodiments, processor 1802 is a central processing unit (CPU), a multi-processor, a distributed processing system, an application specific integrated circuit (ASIC), and/or a suitable processing unit.

In one or more embodiments, computer-readable storage medium 1804 is an electronic, magnetic, optical, electromagnetic, infrared, and/or a semiconductor system (or apparatus or device). For example, computer-readable storage medium 1804 includes a semiconductor or solid-state memory, a magnetic tape, a removable computer diskette, a random-access memory (RAM), a read-only memory (ROM), a rigid magnetic disk, and/or an optical disk. In one or more embodiments using optical disks, computer-readable storage medium 1804 includes a compact disk-read only memory (CD-ROM), a compact disk-read/write (CD-R/W), and/or a digital video disc (DVD).

In one or more embodiments, computer-readable storage medium 1804 stores instructions 1806 configured to cause IC layout diagram generation system 1800 (where such execution represents (at least in part) the EDA tool) to be usable for performing a portion or all the noted processes and/or methods. In one or more embodiments, computer-readable storage medium 1804 further stores information which facilitates performing a portion or all the noted processes and/or methods. In one or more embodiments, computer-readable storage medium 1804 stores a cell library 1807 of cells including such layouts as disclosed herein.

IC layout diagram generation system 1800 includes I/O interface 1810. I/O interface 1810 is coupled to external circuitry. In one or more embodiments, I/O interface 1810 includes a keyboard, keypad, mouse, trackball, trackpad, touchscreen, and/or cursor direction keys for communicating information and commands to processor 1802.

IC layout diagram generation system 1800 further includes network interface 1812 coupled to processor 1802. Network interface 1812 allows IC layout diagram generation system 1800 to communicate with network 1814, to which one or more other computer systems are connected. Network interface 1812 includes wireless network interfaces such as BLUETOOTH, WIFI, WIMAX, GPRS, or WCDMA; or wired network interfaces such as ETHERNET, USB, or IEEE-1364. In one or more embodiments, a portion or all noted processes and/or methods, is implemented in two or more IC layout diagram generation systems 1800.

IC layout diagram generation system 1800 is configured to receive information through I/O interface 1810. The information received through I/O interface 1810 includes one or more of instructions, data, design rules, libraries of standard cells, and/or other parameters for processing by processor 1802. The information is transferred to processor 1802 via bus 1808. IC layout diagram generation system 1800 is configured to receive information related to a UI through I/O interface 1810. The information is stored in computer-readable storage medium 1804 as UI 1842.

In some embodiments, a portion or all the noted processes and/or methods is implemented as a standalone software application for execution by a processor. In some embodiments, a portion or all the noted processes and/or methods is implemented as a software application that is a part of an additional software application. In some embodiments, a portion or all the noted processes and/or methods is implemented as a plug-in to a software application. In some embodiments, at least one of the noted processes and/or methods is implemented as a software application that is a portion of an EDA tool. In some embodiments, a portion or all the noted processes and/or methods is implemented as a software application that is usable by IC layout diagram generation system 1800. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

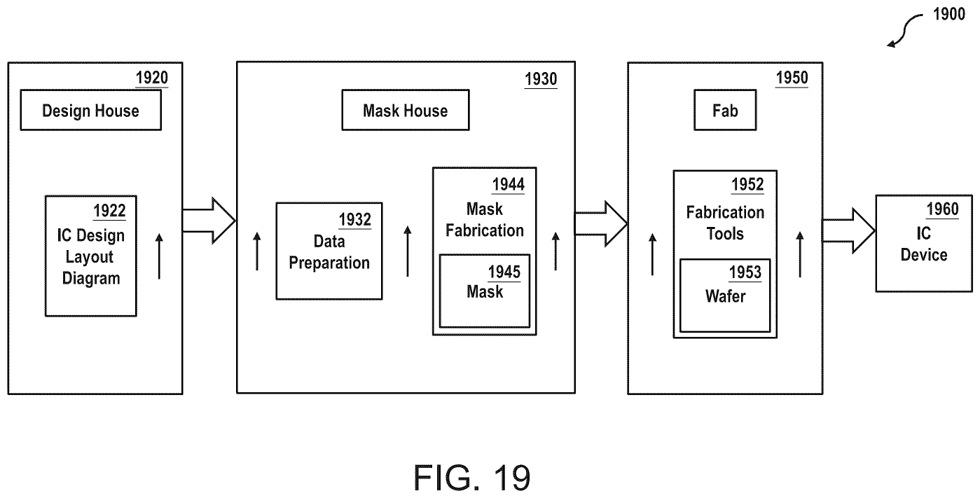

FIG. 19 is a block diagram of IC manufacturing system 1900, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using IC manufacturing system 1900.

In FIG. 19, IC manufacturing system 1900 includes entities, such as a design house 1920, a mask house 1930, and an IC manufacturer/fabricator (“fab”) 1950, that interact with one another in the design, development, and manufacturing cycles and/or services related to manufacturing an IC device 1960. The entities in IC manufacturing system 1900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1920, mask house 1930, and IC fab 1950 are owned by a single larger company. In some embodiments, two or more of design house 1920, mask house 1930, and IC fab 1950 coexist in a common facility and use common resources.

Design house 1920 (or design team) generates an IC design layout diagram 1922. IC design layout diagram 1922 includes various geometrical patterns, e.g., an IC layout diagram discussed herein. The geometrical patterns correspond to patterns of metal, oxide, or semiconductor layers that make up the various components of IC device 1960 to be fabricated. The various layers combine to form various IC features. For example, a portion of IC design layout diagram 1922 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1920 implements a proper design procedure to form IC design layout diagram 1922. The design procedure includes one or more of logic design, physical design or place and route. IC design layout diagram 1922 is presented in one or more data files having information of the geometrical patterns. For example, IC design layout diagram 1922 can be expressed in a GDSII file format or DFII file format.

Mask house 1930 includes mask data preparation 1932 and mask fabrication 1944. Mask house 1930 uses IC design layout diagram 1922 to manufacture one or more masks 1945 usable for fabricating the various layers of IC device 1960 according to IC design layout diagram 1922. Mask house 1930 performs mask data preparation 1932, where IC design layout diagram 1922 is translated into a representative data file (“RDF”). Mask data preparation 1932 provides the RDF to mask fabrication 1944. Mask fabrication 1944 includes a mask writer. A mask writer converts the RDF to an image on a substrate, such as a mask 1945 (reticle) or a semiconductor wafer 1953. The IC design layout diagram 1922 is manipulated by mask data preparation 1932 to comply with characteristics of the mask writer and/or requirements of IC fab 1950. In FIG. 19, mask data preparation 1932 and mask fabrication 1944 are illustrated as separate elements. In some embodiments, mask data preparation 1932 and mask fabrication 1944 are collectively referred to as mask data preparation.

In some embodiments, mask data preparation 1932 includes optical proximity correction (OPC) which uses lithography enhancement techniques to compensate for image errors, such as those that arise from diffraction, interference, other process effects and the like. OPC adjusts IC design layout diagram 1922. In some embodiments, mask data preparation 1932 includes further resolution enhancement techniques (RET), such as off-axis illumination, sub-resolution assist features, phase-shifting masks, other suitable techniques, and the like or combinations thereof. In some embodiments, inverse lithography technology (ILT) is further used, which treats OPC as an inverse imaging problem.

In some embodiments, mask data preparation 1932 includes a mask rule checker (MRC) that checks the IC design layout diagram 1922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1922 to compensate for limitations during mask fabrication 1944, which undoes part of the modifications performed by OPC to meet mask creation rules.

In some embodiments, mask data preparation 1932 includes lithography process checking (LPC) that simulates processing that is implemented by IC fab 1950 to fabricate IC device 1960. LPC simulates this processing based on IC design layout diagram 1922 to create a simulated manufactured device, such as IC device 1960. The processing parameters in LPC simulation include parameters associated with various processes of the IC manufacturing cycle, parameters associated with tools used for manufacturing the IC, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, in response to the simulated device not satisfying design rules, OPC and/or MRC are to be repeated to further refine IC design layout diagram 1922.

The above description of mask data preparation 1932 has been simplified for the purposes of clarity. In some embodiments, mask data preparation 1932 includes additional features such as a logic operation (LOP) to modify the IC design layout diagram 1922 according to manufacturing rules. Additionally, the processes applied to IC design layout diagram 1922 during mask data preparation 1932 are executed in a variety of different orders.

After mask data preparation 1932 and during mask fabrication 1944, a mask 1945 or a group of masks 1945 are fabricated based on the modified IC design layout diagram 1922. In some embodiments, mask fabrication 1944 includes performing one or more lithographic exposures based on IC design layout diagram 1922. In some embodiments, an electron-beam (e-beam) or a mechanism of multiple e-beams is usable to form a pattern on a mask 1945 (photomask or reticle) based on the modified IC design layout diagram 1922. Mask 1945 is formed in various technologies. In some embodiments, mask 1945 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region, and transmits through the transparent regions. In one example, a binary mask version of mask 1945 includes a transparent substrate (e.g., fused quartz) and an opaque material (e.g., chromium) coated in the opaque regions of the binary mask. In another example, mask 1945 is formed using phase shift technology. In a phase shift mask (PSM) version of mask 1945, various features in the pattern formed on the phase shift mask are configured to have proper phase difference to enhance the resolution and imaging quality. In various examples, the phase shift mask is attenuated PSM or alternating PSM. The mask(s) generated by mask fabrication 1944 is usable in a variety of processes. For example, such a mask(s) is usable in an ion implantation process to form various doped regions in semiconductor wafer 1953, in an etching process to form various etching regions in semiconductor wafer 1953, and/or in other suitable processes.

IC fab 1950 is an IC fabrication business that includes one or more manufacturing facilities for the fabrication of a variety of different IC products. In some embodiments, IC fab 1950 is a semiconductor foundry. For example, there is a manufacturing facility for the front-end fabrication of a plurality of IC products (front-end-of-line (FEOL) fabrication), while a second manufacturing facility provides the back-end fabrication for the interconnection and packaging of the IC products (back-end-of-line (BEOL) fabrication), and a third manufacturing facility provides other services for the foundry business.

IC fab 1950 includes wafer fabrication tools 1952 configured to execute various manufacturing operations on semiconductor wafer 1953 such that IC device 1960 is fabricated in accordance with the mask(s), e.g., mask 1945. In various embodiments, wafer fabrication tools 1952 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1950 uses mask 1945 fabricated by mask house 1930 to fabricate IC device 1960. Thus, IC fab 1950 at least indirectly uses IC design layout diagram 1922 to fabricate IC device 1960. In some embodiments, semiconductor wafer 1953 is fabricated by IC fab 1950 using mask 1945 to form IC device 1960. In some embodiments, the IC fabrication includes performing one or more lithographic exposures based at least indirectly on IC design layout diagram 1922. Semiconductor wafer 1953 includes a silicon substrate or other proper substrate having material layers formed thereon. Semiconductor wafer 1953 further includes one or more of various doped regions, dielectric features, multilevel interconnects, and the like (formed at subsequent manufacturing steps).

In some embodiments, a method includes tagging, by a processor, source process design kit (PDK) devices in a source-circuit design; generating, by the processor, a source design simulation database based on source design key performance indicator (KPI) simulation data of the source-PDK devices in the source-circuit design; generating, by the processor, a target-PDK simulation database based on target design KPI simulation data of a plurality of target-PDK devices; creating, by the processor, a matching table based on the source design simulation database; matching, by the processor based on the matching table, one or more target-PDK devices from the target-PDK simulation database with each source-PDK device in the source design simulation database based on source-PDK device KPIs; ranking, by the processor, the one or more target-PDK devices matched from the target-PDK simulation database with each source-PDK device in the source design simulation database based on the source-PDK device KPIs; and exchanging, by the processor based on a migration mapping table that includes a one-to-one relationship for target-PDK devices to the source-PDK devices in the source-circuit design, one or more source-PDK devices in the source-circuit design with one-to-one relational target-PDK devices.

In some embodiments, the tagging the source-PDK devices in the source-circuit design includes reducing, by the processor, the source-circuit design into the source-PDK devices, where each source-PDK device includes one or more physical or functional parameter.

In some embodiments, the tagging the source-PDK devices in the source-circuit design includes categorizing, by the processor, each source-PDK device through a hierarchical tagging, where a user is able to input hierarchies based on a plurality of source-PDK device parameters.

In some embodiments, the tagging the source-PDK devices in the source-circuit design includes determining, by the processor, functionality of each source-PDK device in the source-circuit design; filling, by the processor, PDK parameters for each physical or functional parameter; and creating, by the processor, a tagging table that includes each source-PDK device along with each source-PDK device's PDK parameter.

In some embodiments, the generating the source design simulation database based on the source design KPI simulation data of the source-PDK devices in the source-circuit design includes converting, by the processor, the tagging table into a simulation netlist format to create a netlist; executing, by the processor, a simulation with the netlist; and sending, by the processor, the source design KPI simulation data to the source design simulation database.

In some embodiments, the generating the target-PDK simulation database based on target design KPI simulation data of the plurality of target-PDK devices includes parsing, by the processor, a list of target-PDK devices; and creating, by the processor, a device list of the target-PDK devices.

In some embodiments, the generating the target-PDK simulation database based on the target design KPI simulation data of the plurality of target-PDK devices includes categorizing, by the processor, each target-PDK device through a hierarchical tagging, where a user is able to input hierarchies based on a plurality of target-PDK device parameters; and creating, by the processor, a tagging table that includes each of target-PDK devices along with each of target-PDK device's PDK parameters.

In some embodiments, the generating the target-PDK simulation database based on the target design KPI simulation data of the plurality of target-PDK devices includes converting, by the processor, the tagging table into a simulation netlist format to create a netlist; executing, by the processor, a simulation with the netlist; and sending, by the processor, the target design KPI simulation data to the target-PDK simulation database.

In some embodiments, a system includes a processor; a memory operably coupled to the processor, the memory containing stored instructions, that in response to being executed by the processor cause the system to identify source process design kit (PDK) devices and source-device parameters for each source-PDK device in a source-circuit design; generate a source design simulation database based on source design key performance indicator (KPI) simulation data created by a netlist simulation of the source-PDK devices in the source-circuit design; generate a target-PDK simulation database based on target design KPI simulation data of a plurality of target-PDK devices; match, based on a matching table, one or more target-PDK devices from the target-PDK simulation database with each source-PDK device in the source design simulation database based on source-PDK device KPIs; and exchange, based on a migration mapping table that includes a one-to-one relationship for target-PDK devices to the source-PDK devices in the source-circuit design, one or more source-PDK devices in the source-circuit design with one-to-one relational target-PDK devices.

In some embodiments, the matching the one or more target-PDK devices from the target-PDK simulation database with each source-PDK device in the source design simulation database based on the source-PDK device KPIs includes identify equations within the matching table, where each equation includes device variables; identify the device variables; identify, based upon a location of the device variables in the matching table, correlating conditions for each device variable within the source design simulation database; and identify, based on each correlating condition, a matched device in the target-PDK simulation database.

In some embodiments, the stored instructions, that in response to being executed by the processor further cause the system to screen the target-PDK simulation database; retain each matched target-PDK device that meets a corresponding correlating condition; and store retained matched target-PDK devices in a screened database.

In some embodiments, the stored instructions, that in response to being executed by the processor further cause the system to rank, based on a ranking equation, each retained matched target-PDK device; select each matched target-PDK device that satisfies the ranking question; output a one-to-one table correlating each source-PDK device in the source-circuit design with a matched target-PDK device that satisfies the ranking equation.

In some embodiments, the exchange, based on the migration mapping table that includes the one-to-one relationship for the target-PDK devices to the source-PDK devices in the source-circuit design, the one or more source-PDK devices in the source-circuit design with the one-to-one relational target-PDK devices includes generate a mapping table, based the migration mapping table, that retains PDK related parameters from the migration mapping table; locate the source-PDK devices in a source design schematic openAccess (OA) database according to the mapping table; and write a source-PDK device parameter with a matched target-PDK device's parameter.

In some embodiments, the identifying the source PDK devices and the source-device parameters for each source-PDK device in the source-circuit design includes reduce the source-circuit design into the source-PDK devices, wherein each source-PDK device includes one or more physical or functional parameter.

In some embodiments, the identifying the source PDK devices and the source-device parameters for each source-PDK device in the source-circuit design includes categorize each source-PDK device through hierarchical tagging, where a user is able to input hierarchies based on a plurality of source-PDK device parameters.

In some embodiments, the identifying the source PDK devices and the source-device parameters for each source-PDK device in the source-circuit design includes determine functionality of each source-PDK device in the source-circuit design; fill PDK parameters for each physical or functional parameter; and create a tagging table that includes each source-PDK device along with each source-PDK device's physical or functional parameter.

In some embodiments, a non-transitory computer-readable media having computer-readable instructions stored thereon, which when executed by a processor causes an apparatus to identify source process design kit (PDK) devices and source-PDK device KPI parameters for each source-PDK device in a source-circuit design; generate a source design simulation key performance indicator (KPI) database based on a netlist simulation of source-PDK devices in the source-circuit design; generate a target-PDK device simulation KPI database based on hierarchical tagging of target-PDK devices and on a netlist simulation of the target-PDK devices; match, based on a matching table, one or more target-PDK devices from the target-PDK device simulation KPI database with each source-PDK device in the source-circuit design based on source-PDK device KPIs; and exchange, based on each matched target-PDK device satisfying source-PDK KPI criteria for the source-circuit design, one or more source-PDK devices in the source-circuit design with a matched target-PDK device that satisfies a ranking equation.

In some embodiments, the generating the source design simulation KPI database based on the netlist simulation of the source-PDK devices in the source-circuit design includes convert a tagging table into a simulation netlist format to create a netlist; execute a simulation with the netlist; and send netlist simulation data to the source design simulation KPI database.

In some embodiments, the generating the target-PDK device simulation KPI database based on the hierarchical tagging of the target-PDK devices and on the netlist simulation of the target-PDK devices includes parse a list of the target-PDK devices; and create a device list of the target-PDK devices.

In some embodiments, the generating the target-PDK device simulation KPI database based on the hierarchical tagging of the target-PDK devices and on the netlist simulation of the target-PDK devices includes categorize each of a plurality of target-PDK devices through the hierarchical tagging, where a user is able to input hierarchies based on a plurality of target-PDK device parameters; and create a tagging table that includes each target-PDK device along with each target-PDK device parameter.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should further realize that such equivalent constructions do not depart from the spirit and scope of the present disclosure, and that they may make various changes, substitutions, and alterations herein without departing from the spirit and scope of the present disclosure.

What is claimed is:

1. A method, comprising:
tagging, by a processor, source process design kit (PDK) devices in a source-circuit design;
generating, by the processor, a source design simulation database based on source design key performance indicator (KPI) simulation data of the source-PDK devices in the source-circuit design;
generating, by the processor, a target-PDK simulation database based on target design KPI simulation data of a plurality of target-PDK devices;
creating, by the processor, a matching table based on the source design simulation database;
matching, by the processor based on the matching table, one or more target-PDK devices from the target-PDK simulation database with each source-PDK device in the source design simulation database based on source-PDK device KPIs;
ranking, by the processor, the one or more target-PDK devices matched from the target-PDK simulation database with each source-PDK device in the source design simulation database based on the source-PDK device KPIs; and
exchanging, by the processor based on a migration mapping table that includes a one-to-one relationship for target-PDK devices to the source-PDK devices in the source-circuit design, one or more source-PDK devices in the source-circuit design with one-to-one relational target-PDK devices.

2. The method of claim 1, wherein the tagging the source-PDK devices in the source-circuit design comprises:
reducing, by the processor, the source-circuit design into the source-PDK devices, where each source-PDK device includes one or more physical or functional parameters.

3. The method of claim 1, wherein the tagging the source-PDK devices in the source-circuit design comprises:
categorizing, by the processor, each source-PDK device through a hierarchical tagging, where a user is able to input hierarchies based on a plurality of source-PDK device parameters.

4. The method of claim 1, wherein the tagging the source-PDK devices in the source-circuit design comprises:
determining, by the processor, functionality of each source-PDK device in the source-circuit design;
filling, by the processor, PDK parameters for each physical or functional parameter; and
creating, by the processor, a tagging table that includes each source-PDK device along with each source-PDK device's PDK parameter.

5. The method of claim 4, wherein the generating the source design simulation database based on the source design KPI simulation data of the source-PDK devices in the source-circuit design comprises:
converting, by the processor, the tagging table into a simulation netlist format to create a netlist;
executing, by the processor, a simulation with the netlist; and
sending, by the processor, the source design KPI simulation data to the source design simulation database.

6. The method of claim 1, wherein the generating the target-PDK simulation database based on target design KPI simulation data of the plurality of target-PDK devices comprises:
parsing, by the processor, a list of target-PDK devices; and
creating, by the processor, a device list of the target-PDK devices.

7. The method of claim 1, wherein the generating the target-PDK simulation database based on the target design KPI simulation data of the plurality of target-PDK devices comprises:
categorizing, by the processor, each target-PDK device through a hierarchical tagging, where a user is able to input hierarchies based on a plurality of target-PDK device parameters; and
creating, by the processor, a tagging table that includes each of target-PDK devices along with each of target-PDK device's PDK parameters.

8. The method of claim 7, wherein the generating the target-PDK simulation database based on the target design KPI simulation data of the plurality of target-PDK devices comprises:
converting, by the processor, the tagging table into a simulation netlist format to create a netlist;
executing, by the processor, a simulation with the netlist; and
sending, by the processor, the target design KPI simulation data to the target-PDK simulation database.

9. A system, comprising:
a processor;
a memory operably coupled to the processor, the memory containing stored instructions, that in response to being executed by the processor cause the system to:
identify source process design kit (PDK) devices and source-device parameters for each source-PDK device in a source-circuit design;
generate a source design simulation database based on source design key performance indicator (KPI) simulation data created by a netlist simulation of the source-PDK devices in the source-circuit design;
generate a target-PDK simulation database based on target design KPI simulation data of a plurality of target-PDK devices;
match, based on a screening condition table, one or more target-PDK devices from the target-PDK simulation database with each source-PDK device in the source design simulation database based on source-PDK device KPIs; and
exchange, based on a migration mapping table that includes a one-to-one relationship for target-PDK devices to the source-PDK devices in the source-circuit design, one or more source-PDK devices in the source-circuit design with one-to-one relational target-PDK devices.

10. The system of claim 9, wherein the matching the one or more target-PDK devices from the target-PDK simulation database with each source-PDK device in the source design simulation database based on the source-PDK device KPIs comprises:
identify equations within the matching table, where each equation includes device variables;
identify the device variables;
identify, based upon a location of the device variables in the matching table, correlating conditions for each device variable within the source design simulation database; and
identify, based on each correlating condition, a matched device in the target-PDK simulation database.

11. The system of claim 10, wherein the stored instructions, that in response to being executed by the processor further cause the system to:
screen the target-PDK simulation database;
retain each matched target-PDK device that meets a corresponding correlating condition; and
store retained matched target-PDK devices in a screened database.

12. The system of claim 11, wherein the stored instructions, that in response to being executed by the processor further cause the system to:
rank, based on a ranking equation, each retained matched target-PDK device;
select each matched target-PDK device that satisfies the ranking equation;
output a one-to-one table correlating each source-PDK device in the source-circuit design with the selected matched target-PDK device that satisfies the ranking equation.

13. The system of claim 9, wherein the exchange, based on the migration mapping table that includes the one-to-one relationship for the target-PDK devices to the source-PDK devices in the source-circuit design, the one or more source-PDK devices in the source-circuit design with the one-to-one relational target-PDK devices comprises:
generate a mapping table, based the migration mapping table, that retains PDK related parameters from the migration mapping table;
locate the source-PDK devices in a source design schematic openAccess (OA) database according to the mapping table; and
write a source-PDK device parameter with a matched target-PDK device's parameter.

14. The system of claim 9, wherein the identifying the source PDK devices and the source-device parameters for each source-PDK device in the source-circuit design comprises:
reduce the source-circuit design into the source-PDK devices, wherein each source-PDK device includes one or more physical or functional parameters.

15. The system of claim 9, wherein the identifying the source PDK devices and the source-device parameters for each source-PDK device in the source-circuit design comprises:
categorize each source-PDK device through hierarchical tagging, where a user is able to input hierarchies based on a plurality of source-PDK device parameters.

16. The system of claim 9, wherein the identifying the source PDK devices and the source-device parameters for each source-PDK device in the source-circuit design comprises:
determine functionality of each source-PDK device in the source-circuit design;
fill PDK parameters for each physical or functional parameter; and
create a tagging table that includes each source-PDK device along with each source-PDK device's physical or functional parameter.

17. A non-transitory computer-readable media having computer-readable instructions stored thereon, which when executed by a processor causes an apparatus to:
identify source process design kit (PDK) devices and source-PDK device KPI parameters for each source-PDK device in a source-circuit design;
generate a source design simulation key performance indicator (KPI) database based on a netlist simulation of source-PDK devices in the source-circuit design;
generate a target-PDK device simulation KPI database based on hierarchical tagging of target-PDK devices and on a netlist simulation of the target-PDK devices;
match, based on a matching table, one or more target-PDK devices from the target-PDK device simulation KPI database with each source-PDK device in the source-circuit design based on source-PDK device KPIs; and
exchange, based on each matched target-PDK device satisfying source-PDK KPI criteria for the source-circuit design, one or more source-PDK devices in the source-circuit design with a ranked matched target-PDK device.

18. The non-transitory computer-readable media of claim 17, wherein the generating the source design simulation KPI database based on the netlist simulation of the source-PDK devices in the source-circuit design comprises:
convert a tagging table into a simulation netlist format to create a netlist;
execute a simulation with the netlist; and
send netlist simulation data to the source design simulation KPI database.

19. The non-transitory computer-readable media of claim 17, wherein the generating the target-PDK device simulation KPI database based on the hierarchical tagging of the target-PDK devices and on the netlist simulation of the target-PDK devices comprises:
parse a list of the target-PDK devices; and
create a device list of the target-PDK devices.

20. The non-transitory computer-readable media of claim 17, wherein the generating the target-PDK device simulation KPI database based on the hierarchical tagging of the target-PDK devices and on the netlist simulation of the target-PDK devices comprises:
categorize each of a plurality of target-PDK devices through the hierarchical tagging, where a user is able to input hierarchies based on a plurality of target-PDK device parameters; and
create a tagging table that includes each target-PDK device along with each target-PDK device parameter.
